(19) United States
(12) Patent Application Publication
(10) Pub. No.: US 2023/0343579 A1
(43) Pub. Date: Oct. 26, 2023

(54) SEMICONDUCTOR DEVICE AND MANUFACTURING METHOD THEREOF

(71) Applicant: National Tsing Hua University, Hsinchu City (TW)

(72) Inventors: Po-Wen Chiu, Hsinchu City (TW); Chao-Hui Yeh, Yunlin County (TW)

(73) Assignee: National Tsing Hua University, Hsinchu City (TW)

(21) Appl. No.: 17/834,946

(22) Filed: Jun. 8, 2022

(30) Foreign Application Priority Data
Apr. 22, 2022 (TW) 111115375

(51) Int. Cl. H01L 21/02; H01L 21/3065

(52) U.S. Cl. CPC H01L 21/02112; H01L 21/3065

(57) ABSTRACT

A semiconductor device includes a substrate, a bottom sublayer having a monoatomic layer thickness, disposed on the substrate, located at a bottom of the device, and extending in a horizontal direction, a metal sublayer having a monoatomic layer thickness, overlaying the bottom sublayer in the horizontal direction and electrically connected to the bottom sublayer, a top sublayer having a monoatomic layer thickness, disposed in the horizontal direction and electrically connected to the metal sublayer, and a contact metal layer disposed above the metal sublayer. A top surface of the contact metal layer is higher than a top surface of the top sublayer. Bottom layer contact metal atoms of the contact metal layer directly form corresponding bonds with a metal atom surface of the metal sublayer exposed after a portion of the top sublayer is stripped.

Original corresponding bonds are maintained between the metal sublayer and the bottom sublayer.

### CROSS-REFERENCE TO RELATED APPLICATION

This application claims the priority benefit of Taiwan application serial no. 111115375, filed on Apr. 22, 2022. The entirety of the above-mentioned patent application is hereby incorporated by reference herein and made a part of this specification.

### BACKGROUND

### Technical Field

The disclosure relates to a layered semiconductor electronic device with low contact resistance and a manufacturing method thereof.

### Description of Related Art

In recent years, the semiconductor industry has continuously improved device performance by shrinking transistor scales. However, the increasingly shrinking devices are bound to face bottlenecks in process technology and device operations. Therefore, it is imperative to seek alternative materials and introduce new device design and manufacturing concepts. Two-dimensional layered semiconductor materials with only an atomic layer thickness has gradually attracted much attention due to their rapid rise. Since the two-dimensional layered semiconductor has only a thickness of a few atomic layers, material properties thereof are completely different from that of three-dimensional bulk materials. Further, and the two-dimensional layered semiconductor exhibits special optical properties, quantum properties, and high carrier mobility, thermal conductivity, rigidity, etc., and meanwhile has advantages of low power consumption and scaled-down device size. Therefore, the two-dimensional layered semiconductor may be used as a preferred channel material for the minimization of semiconductor devices in the future.

Since a characteristic constant of the two-dimensional material is much smaller than a technical bottleneck of a short-channel effect encountered by the three-dimensional material, and there is no dangling bond on the surface of the material, the carrier mobility will not be affected by surface scattering. If the number of atomic layers of the material channel may be reduced, the channel length provided by the manufacturing process of the related art may be satisfied, and the short channel effect may be solved. However, due to the high contact resistance between the channel and source drain contact points, a bottleneck in application is generated.

In the common method aiming to reduce the contact resistance between metal and the two-dimensional semiconductor provided by the related art, an intercalation layer is placed between the metal and the two-dimensional semiconductor to separate coupling of d orbital electrons between the two materials to address the problem of Fermi-level pinning. However, the existence of the intercalation layer increases a tunneling resistance of electrons and it is difficult in implementation. In addition, the intercalation layer must be fabricated by a peel-and-stick transfer process, which is completely incompatible with the silicon process provided by the related art.

Therefore, how to greatly reduce the contact resistance of the two-dimensional layered semiconductor in a way that is compatible with the standard semiconductor process and by using new process equipment has become a common challenge in the era of heterostructure integration.

The information disclosed in this BACKGROUND section is only for enhancement of understanding of the background of the described technology and therefore it may contain information that does not form the prior art that is already known to a person of ordinary skill in the art. Further, the information disclosed in the Background section does not mean that one or more problems to be resolved by one or more embodiments of the disclosure was acknowledged by a person of ordinary skill in the art.

### SUMMARY

The disclosure provides a layered semiconductor electronic device and a manufacturing method thereof capable of reducing a contact resistance caused by a manufacturing process provided by the related art.

The disclosure provides a semiconductor device including a substrate, a bottom sublayer, a metal sublayer, a top sublayer, and a contact metal layer. The bottom sublayer has a monoatomic layer thickness, is disposed on the substrate and located at a bottom of the semiconductor device, and extends in a horizontal direction. The metal sublayer has a monoatomic layer thickness, overlays the bottom sublayer, and is electrically connected to the bottom sublayer in a manner of extending in the horizontal direction. The top sublayer has a monoatomic layer thickness and is disposed above a portion of the metal sublayer and electrically connected to the metal sublayer in the manner of extending in the horizontal direction. The contact metal layer is disposed above another portion of the metal sublayer. A top surface of the contact metal layer is higher than a top surface of the top sublayer. A plurality of bottom layer contact metal atoms of the contact metal layer directly form corresponding bonds with a metal atom surface of the metal sublayer exposed after a portion of the top sublayer is stripped, and original corresponding bonds are maintained between the metal sublayer and the bottom sublayer.

The disclosure provides a manufacturing method of a semiconductor device, and the manufacturing method includes the following steps. A monolayer film composed of three monoatomic sublayers is formed in a substrate. The three monoatomic sublayers include a bottom sublayer arranged on the substrate and located at a bottom of the semiconductor device and forming a monoatomic layer extending in a horizontal direction, a metal sublayer overlaying the bottom sublayer and electrically connected to the bottom sublayer in the form of a monoatomic layer extending in the horizontal direction, a top sublayer arranged above a portion of the metal sublayer and electrically connected to the metal sublayer in the form of a monoatomic layer extending in the horizontal direction, and a contact metal layer disposed above another portion of the metal sublayer. A top surface of the contact metal layer is higher than a top surface of the top sublayer. A portion of the top sublayer is uniformly stripped in a process chamber and original corresponding bonds are maintained between the metal sublayer and the bottom sublayer. A deposition process is performed in the process chamber, so that a plurality of bottom layer contact metal atoms of the contact metal layer directly form corresponding bonds with metal atoms of the exposed metal sublayer at a position where the top sublayer is uniformly stripped.

Based on the above description, by selectively stripping the atoms of the first layer of the two-dimensional semiconductor surface, a contact electrode is directly plated without changing the process environment and position, a good metal-semiconductor junction is thereby generated and the contact resistance is reduced. By enhancing the electron orbital coupling between the contact metal and the semiconductor, the density of states near a transmission band is increased, and efficiency of electron injection is thereby improved.

To make the aforementioned more comprehensible, several embodiments accompanied with drawings are described in detail as follows.

### BRIEF DESCRIPTION OF THE DRAWINGS

The various aspects of the disclosure are best understood by reading the following detailed description together with the accompanying drawings. It should be noted that in accordance with standard practice in the industry, the various features are not drawn to scale. In fact, the dimensions of the various features may be arbitrarily increased or decreased for clarity of description.

FIG. 1 is a schematic structural diagram illustrating a layered semiconductor device according to some embodiments.

FIG. 2 is a flow chart illustrating a manufacturing method of a layered semiconductor device according to some embodiments.

FIG. 3A to FIG. 3G are schematic diagrams illustrating structures of various stages in a manufacturing process of a layered semiconductor device according to some embodiments.

FIG. 4 is a schematic top view illustrating a layered semiconductor device according to some embodiments.

FIG. 5 is a schematic diagram illustrating process equipment of a layered semiconductor device according to some embodiments.

FIG. 6 is a flow chart illustrating steps of an exemplary manufacturing method of a layered semiconductor device according to some embodiments.

### DESCRIPTION OF THE EMBODIMENTS

The following disclosure provides many different embodiments or examples for implementing different features of a provided subject. Specific examples of components and arrangements are set forth below to simplify the disclosure. Certainly, these are only examples and are not intended to be limiting. For example, in the following descriptions, a first feature being formed “above” or “on” a second feature may include embodiments in which the first feature and the second feature are formed in direct contact, and may also include embodiments in which additional features may be formed between the first feature and the second feature such that the first feature may not be in direct contact with the second feature. Moreover, the disclosure may reuse reference numbers and/or letters in various embodiments. Such reuse is for the purpose of brevity and clarity rather than representing the relationship between the various embodiments and/or configurations.

Moreover, for ease of description, spatial relative terms such as “beneath”, “below”, “lower”, “above”, “upper”, etc., may be used to describe a relationship between one element or feature and another (other) element or feature shown in the figure. The spatial relative terms are intended to encompass different orientations of the device in use or operation in addition to the orientation depicted in the figures. The device may have other orientations (rotated 90 degrees or at other orientations), and the spatial relative terms used herein may be interpreted accordingly.

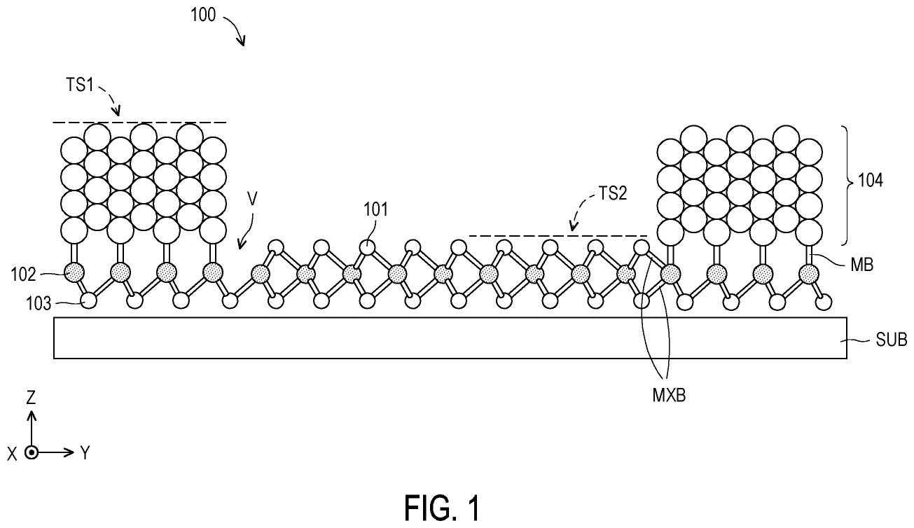

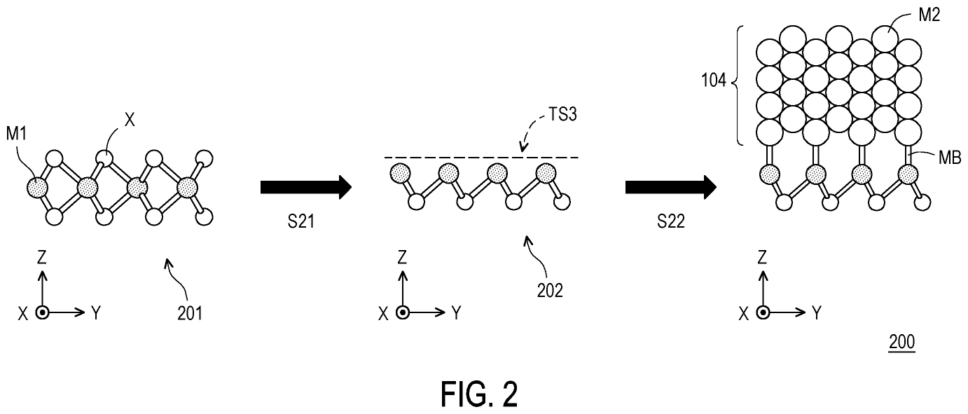

FIG. 1 is a schematic structural diagram illustrating a layered semiconductor device 100 according to some embodiments. FIG. 2 is a flow chart illustrating a manufacturing method of a layered semiconductor device according to some embodiments. Directions X, Y, and Z construct a set of orthogonal Cartesian coordinates.

Referring to FIG. 1, the semiconductor device according to an embodiment of the disclosure includes: a substrate, a bottom sublayer, a metal sublayer, a top sublayer, and a contact metal layer.

In some embodiments, the process shown in FIG. 2 may be a front-end-of-line (FEOL) process, and a substrate SUB may be a semiconductor substrate, such as a semiconductor material (for example, a single crystal semiconductor material) that may or may not be doped with impurities (for example, boron), a semiconductor-on-insulator substrate, etc. In some embodiments, the substrate SUB may include one or more semiconductor materials. For example, the one or more semiconductor materials may be an elemental semiconductor material, a compound semiconductor material, or a semiconductor alloy. The semiconductor material may include at least one of silicon, germanium, or silicon germanium, or an III-V compound semiconductor (for example, GaP, GaAs, or GaSb). For example, the elemental semiconductor may include Si or Ge. The compound semiconductor material and the semiconductor alloy may respectively include SiGe, SiC, SiGeC, III-V semiconductor materials, II-VI semiconductor materials, or semiconductor oxide materials. The semiconductor oxide material may be one or a plurality of ternary or higher (for example, quaternary, etc.) semiconductor oxides, such as indium gallium zinc oxide (IGZO), indium zinc oxide (IZO) or indium tin oxide (indium tin oxide, ITO), etc. In some embodiments, the substrate SUB may be a semiconductor-on-insulator including at least one layer (for example, an oxide layer) of a dielectric material disposed between a pair of semiconductor layers (for example, silicon layers). Depending on the circuit and actual requirements, the substrate SUB may include a doped region (for example, a p-type semiconductor substrate or an n-type semiconductor substrate). In some embodiments, the doped region may be doped with a p-type dopant or an n-type dopant. In some embodiments, the substrate SUB is a sapphire (Al₂O₃) substrate.

In some alternative embodiments, the process shown in FIG. 2 may be a middle-end-of-line (MEOL) process, a back-end-of-line (BEOL) process, and the substrate SUB may be, for example, an inter-layer dielectric layer formed on a conductive pattern of an interconnect structure (not shown) and other inter-layer dielectric layers, where the interconnect structure is formed on a semiconductor substrate (not shown) containing FEOL process devices. In such embodiment, the substrate SUB may include a low dielectric constant dielectric material, such as xerogel, aerogel, amorphous carbon fluoride, parylene, bis-benzocyclobutene (BCB), flare, hydrogen silsesquioxane (HSQ), silicon oxide fluoride (SiOF), combinations thereof, etc.

In some embodiments, the device 100 made of a two-dimensional semiconductor material is formed on the substrate SUB. In some embodiments, the device 100 is a monolayer of the two-dimensional semiconductor material. In some embodiments, the device 100 includes one or a plurality of monolayers of the two-dimensional semiconductor material stacked on each other along a Z-direction. The number of the stacked monolayers is not particularly limited as long as the two-dimensional semiconductor material maintains semiconductor properties or semiconductor-like properties. In some embodiments, the two-dimensional semiconductor material may contain a single type of atoms, or may contain different types of atoms. For example, the two-dimensional semiconductor material may be graphene, phosphorene, transition metal chalcogenide (for example, InSe), transition metal dichalcogenide (for example, MX₂, where M is, for example, Mo, W , Zr, Hf, Sn, V, Pt, or Pd, and X is S, Se, or Te), etc. Examples of the transition metal dichalcogenide include MoS₂, MoSe₂, MoTe₂, WS₂, WSe₂, WTe₂, ZrS₂, ZrSe₂, HfS₂, HfSe₂, SnS₂, SnSe₂, VSe₂, VTe₂, PtSe₂, PtTe₂, and PdSe₂. In some embodiments, dopants may be implanted or other impurities may be generated to adjust semiconducting properties of the two-dimensional semiconductor material. In some embodiments, the two-dimensional semiconductor material may be fabricated or provided by any suitable process. For example, chemical vapor deposition (CVD), physical vapor deposition (PVD), atomic layer deposition (ALD), molecular beam epitaxy (MBE), chemical vapor transport (CVT), etc., may be used to grow the two-dimensional semiconductor material.

In some embodiments, a deposition temperature may be within a range of 15° C. to 45° C., and a deposition pressure may be within a range of 10⁻⁴ Torr to 10⁻⁹ Torr. In some embodiments, the deposition temperature may be within a range of 300° C. to 800° C., and the deposition pressure may be in a range of 1 Torr to 800 Torr. In some embodiments, the two-dimensional semiconductor material may be obtained by ablating or peeling a bulk material, and one or a plurality of monolayers may be transferred to the substrate SUB through, for example, a sacrificial tape or support member containing a polymer material and/or metallic material, where a transfer method thereof is not limited here. In some alternative embodiments, a transition metal film disposed on the substrate SUB may be reacted with chalcogen to generate a monolayer in situ.

Referring to FIG. 1 and FIG. 2, in some embodiments, a top sublayer 101 is disposed above the substrate SUB, and a bottom sublayer 103 is located at the bottom of the semiconductor device 100. In some embodiments, atoms in the bottom sublayer 103 are arranged by extending in a horizontal direction (an X-Y plane direction shown in FIG. 1), where the bottom sublayer 103 has a thickness of a monoatomic layer. In some embodiments, the bottom sublayer 103 is composed of a plurality of identical chalcogenide non-metallic elements X without containing oxygen atoms, where X may be S, Se, or Te. In some embodiments, the bottom sublayer 103 is composed of a plurality of different chalcogenide non-metallic elements X that do not contain oxygen atoms.

Referring to FIG. 1 and FIG. 2, in some embodiments, a metal sublayer 102 overlays the bottom sublayer 103, and atoms in the metal sublayer 102 are arranged by extending in the horizontal direction. In some embodiments, the metal sublayer 102 and the bottom sublayer 103 are electrically connected to each other. Specifically, the metal sublayer 102 and the bottom sublayer 103 form covalent bonds MXB with each other. The metal sublayer 102 has a thickness of a monoatomic layer. In some embodiments, the metal sublayer 102 is composed of transition metal atoms M1, where M1 may be V, Nb, Ta, Ti, Hf, Mo, W, Pd, or Pt.

In some embodiments, the metal sublayer includes at least one of or a combination of transition metal elements, semi-metal elements, and noble metal elements.

Referring to FIG. 1 and FIG. 2, in some embodiments, the top sublayer 101 is disposed above a portion of the metal sublayer 102, and atoms in the top sublayer 101 are arranged by extending in the horizontal direction. In some embodiments, the top sublayer 101 and the metal sublayer 102 are electrically connected to each other. Specifically, the metal sublayer 102 and the top sublayer 101 form covalent bonds MXB with each other. The top sublayer 101 has a thickness of a monoatomic layer. In some embodiments, the top sublayer 101 is composed of a plurality of identical chalcogenide non-metallic elements X without oxygen atoms, where X may be S, Se, or Te.

Referring to FIG. 1 and FIG. 2, in some embodiments, the top sublayer 101 is composed of a plurality of different chalcogenide non-metallic elements X that do not contain oxygen atoms.

Referring to FIG. 1 and FIG. 2, in some embodiments, the top sublayer 101 and the bottom sublayer 103 are composed of a plurality of elements of a same family in the periodic table. Specifically, the top sublayer 101 and the bottom sublayer 103 are composed of the same chalcogenide non-metallic element X. In some embodiments, the top sublayer 101 and the bottom sublayer 103 are composed of different chalcogenide non-metallic elements X. In some embodiments, the bottom sublayer 103 and the top sublayer 101 are composed of a plurality of identical elements.

Referring to FIG. 1 and FIG. 2, in some embodiments, the top sublayer 101, the metal sublayer 102 and the bottom sublayer 103 form transition metal dichalcogenides (TMDs), where the TMDs are semiconductor compounds with energy gaps. Specifically, bulk TMDs form a plurality of ordered hexagonal ring-bound crystal structures, in which transition metal atoms are located at 1, 3, 5 on the ring and chalcogen atom pairs are located at 2, 4, 6 on the ring (not shown in the figure). The chalcogen atoms are paired up and down, and each chalcogen atom and the transition metal atom are not in a same plane. The TMDs are a monolayer film 201 of three-atom-thick when being viewed from a side (an X-Z plane direction).

Referring to FIG. 1 and FIG. 2, in some embodiments, the top sublayer 101, the metal sublayer 102, and the bottom sublayer 103 form a TMDs two-dimensional monolayer film 201 composed of three monoatomic sublayers. The formed TMDs two-dimensional monolayer film 201 is a direct energy gap semiconductor and has flexibility, high lubricity and certain transparency. It should be noted that the two-dimensional monolayer film 201 of TMDs may be formed into a bulk two-dimensional semiconductor material through layered stacking. A van der Waals force exists between the layers. Therefore, a mechanical exfoliation method or a chemical ion intercalation and exfoliation method may be used to achieve a two-dimensional material with a monolayer atomic level thickness. In some embodiments, in the TMDs two-dimensional monolayer film 201, the metal sublayer 102 may be sandwiched between the top sublayer 101 and the bottom sublayer 103. In some embodiments, a van der Waals gap separates a monolayer of the metal sublayer 102 from an overlaying element regardless of whether the overlying element is a monolayer of the top sublayer 101, a gate dielectric material or other metal contact materials.

In some embodiments, conductive properties of the material of the TMDs two-dimensional monolayer film 201 include properties of metal, semi-metal, semiconductor, and insulator, and may be applied to devices materials of electronic, optoelectronic, spintronic, and semiconductor. In addition, due to an excellent electron transport property and high carrier mobility of the TMDs two-dimensional monolayer film 201, it may be applied to fields such as flexible transistors, memories, optoelectronic components, sensors, solar cells, etc. In some embodiments, since the TMDs two-dimensional monolayer film 201 has a transparent property and flexibility, and is a direct energy gap semiconductor, it may be fabricated into a transparent light-emitting diode (LED). Since different materials have different energy gaps, they may be used to produce transparent LEDs, and may also be applied to light-transmitting thin displays or transferred to clothing and human skin. In some embodiments, a performance of photoluminescence may be increased when the double-layer TMDs two-dimensional monolayer film 201 is stressed, so as to fabricate photonic computing processors with higher luminous efficiency and high-efficiency photosensors. In some embodiments, the material of the TMDs two-dimensional monolayer film 201 has high lubricity, and may be combined with nanodiamonds to form a low-friction solid lubricant, which may be used in various machinery-related industries.

Referring to FIG. 1 and FIG. 2, in some embodiments, the contact metal layer 104 is disposed above another portion of the metal sublayer 102 (i.e., the portion that is not etched by hydrogen radicals generated by hydrogen plasma at room temperature, which is described below), where a top surface TS1 of the contact metal layer 104 is higher than a top surface TS2 of the top sublayer 101. In some embodiments, the contact metal layer 104 may be a polyatomic layer structure, and the contact metal layer 104 may be separated by the top sublayer 101 and laterally separated from each other in the horizontal direction (the X-Y plane direction shown in FIG. 1). In some embodiments, the number of the contact metal layers 104 is not particularly limited, which may be selected to adjust the properties or work function of the contact metal layers 104. In some embodiments, the contact metal layer 104 may serve as at least one of a work function material and a gate electrode material. In some embodiments, the work function material may be selected according to a desired conductivity type of a transistor, so as to adjust a threshold voltage of the transistor. For example, p-type work function materials include TiN, TaN, Ru, Mo, Al, WN, ZrSi₂, MoSi₂, TaSi₂, NiSi₂, WN, other suitable p-type work function materials, or combinations thereof. On the other hand, n-type work function materials include, for example, Ti, Ag, TaAl, TaAlC, TiAlN, TaC, TaCN, TaSiN, Mn, Zr, other suitable n-type work function materials, or combinations thereof. In some embodiments, the gate electrode material includes titanium (Ti), tantalum (Ta), tungsten (W), aluminum (Al), zirconium (Zr), hafnium (Hf), titanium aluminum (TiAl), tantalum aluminum (TaAl), tungsten aluminum (WAl), zirconium aluminum (ZrAl), hafnium aluminum (HfAl), titanium nitride (TiN), tantalum nitride (TaN), titanium silicon nitride (TiSiN), tantalum silicon nitride (TaSiN), tungsten silicon nitride (WSiN), titanium carbide (TiC), tantalum carbide (TaC), titanium aluminum carbide (TiAlC), tantalum aluminum carbide (TaAlC), titanium aluminum nitride (TiAlN), tantalum aluminum nitride (TaAlN), any other suitable metal-containing material, or combinations thereof. In some embodiments, in some embodiments, a method of providing the work function material and/or gate electrode material includes performing at least one suitable deposition technique, such as chemical vapor deposition (CVD), plasma enhanced chemical vapor deposition (PECVD), atomic layer deposition (ALD), remote plasma assisted atomic layer deposition (RPALD), plasma assisted atomic layer deposition (PEALD), molecular beam epitaxy (MBE), etc.

In some embodiments, a material of the contact metal layer 104 includes cobalt (Co), tungsten (W), copper (Cu), titanium (Ti), tantalum (Ta), aluminum (Al), zirconium (Zr), hafnium (Hf), gold (Au)), molybdenum (Mo), bismuth (Bi), antimony (Sb), combinations thereof, or other suitable metals or alloys.

Referring to FIG. 1 and FIG. 2, in some embodiments, a chemical reactive etching S21 is performed by the hydrogen radicals generated by the hydrogen plasma in a process chamber at room temperature to precisely and uniformly strip a portion of the top sublayer 101. In some embodiments, the uniform stripping means that regarding a hydrogen ion source located in the process chamber, under the conditions of precisely controlling a predetermined hydrogen concentration and a predetermined reaction time, the hydrogen radicals generated by hydrogen plasma provided by the hydrogen ion source at room temperature are used to strip a portion of the top sublayer 101 having a monoatomic layer within a specific range. The predetermined hydrogen concentration and the predetermined reaction time may be set according to an actual requirement, and are not limited by the disclosure. At this time, a top surface TS3 of the transition metal atoms M1 of the metal sublayer 102 that is partially exposed through stripping of the hydrogen plasma or hydrogen radicals may form dangling bonds (not shown) to directly form metal bonds corresponding to each other with a plurality of bottom contact metal atoms M2 in the contact metal layer 104 in the process chamber at room temperature. To be specific, the bottom contact metal atoms M2 of the contact metal layer 104 and the transition metal atoms M1 on the surface of the metal sublayer 102 form the metal bonds MB with respective d orbital domains. It should be noted that the original corresponding covalent bonds MXB are still maintained between the transition metal atoms M1 in the metal sublayer 102 and the chalcogenide non-metallic elements X in the bottom sublayer 103 without being stripped by the chemical reactive etching S21 performed by the hydrogen radicals generated by the hydrogen plasma. Namely, the hydrogen radicals generated by the hydrogen plasma at room temperature and a portion of the top sublayer 101 within a defined range may have the chemical reactive etching S21 instead of using physical ion bombardment, so that the covalent bonds MXB between the bottom sublayer 103 and the metal sublayer 102 are not broken.

Besides, referring to FIG. 1 and FIG. FIG. 2, in some embodiments, after the hydrogen plasma treatment, a portion of the transition metal atoms M1 with dangling bonds (not shown) on the top surface TS3 of the exposed metal sublayer 102 still remain the original corresponding covalent bonds MXB with a part of the chalcogenide non-metal elements X in the top sublayer 101 that is not stripped by chemical etching of the hydrogen plasma.

Referring to FIG. 1 and FIG. 2, in some embodiments, there is no covalent bond MXB between the transition metal atoms M1 of the exposed metal sublayer 102 and a part of the chalcogenide non-metal atoms X in the top sublayer 101 to generate vacancies V.

Referring to FIG. 1 and FIG. 2, in some embodiments, a process condition of the chemical reactive etching S21 produced by hydrogen plasma and the chalcogenide non-metallic elements X in the top sublayer 101 is that hydrogen radicals are generated to carry on the chemical reactive etching at a room temperature and a process pressure of about 10⁻³ to 100 Torr. A general reaction formula of the chemical reactive etching S21 is H_{2(g)}+X₍ₛ₎→H₂X_{(g)}.

Referring to FIG. 1 and FIG. 2, in some embodiments, after the hydrogen plasma in the process chamber strips a portion of the top sublayer 101, the bottom sublayer 103 and the exposed metal sublayer 102 form a monolayer film 202 composed of two layers of atoms. The top surface TS3 of the exposed metal sublayer 102 has dangling bonds (not shown), so that when the contact metal layer 104 in the process chamber is subjected to a deposition process S22, it may directly form surface edge metal bonds MB with the exposed metal sublayer 102. It should be noted that the following deposition process S22 may be performed on the metal sublayer 102 subjected to the hydrogen plasma etching S21 in the process chamber (i.e., in-situ deposition or in-situ growth) while the process chamber maintains an original vacuum environment (i.e., not breaking the vacuum). That is, the process of hydrogen plasma etching S21 and the deposition process S22 of the contact metal layer 104 are all performed in the same process chamber, which may avoid the interference caused by water oxygen or other impurity ions. Since the contact metal layer 104 may directly generate the metal bonds MB when contacting the metal sublayer 102, a contact resistance may be reduced.

Referring to FIG. 1 and FIG. 2, in some embodiments, when the deposition process S22 is continuously performed in the process chamber, a process pressure is controlled at about 10⁻⁴ to 10⁻⁹ Torr. In some embodiments, the deposition process S22 may be implemented by chemical vapor deposition (CVD), physical vapor deposition (PVD), atomic layer deposition (ALD), plating, other deposition techniques, or a combination thereof.

Referring to FIG. 1 and FIG. 2, in some embodiments, after the deposition process S22, a relatively small contact resistance value is formed between the contact metal layer 104 and the metal sublayer 102. In some embodiments, the contact resistance value between the contact metal layer 104 and the metal sublayer 102 is less than 1 kΩ·μm.

In some embodiments, the contact metal layer 104 may be disposed on a side edge of the TMDs two-dimensional monolayer film 201 to form edge contact with a transition metal atom M1 of the metal sublayer 102 of the TMDs two-dimensional monolayer film 201. Namely, the contact of the contact metal layer 104 with the TMDs two-dimensional monolayer film 201 may occur from the side rather than involving the top surface or the bottom surface of the TMDs two-dimensional monolayer film 201. In some embodiments, the contact metal layer 104 may be simultaneously disposed at the side edge of the TMDs two-dimensional monolayer film 201 and above a portion of the metal sublayer 102 to form combined contact. For example, the contact metal layer 104 may form metal bonds MB with the transition metal atoms M1 on the side and the top surface of the metal sublayer 102 of the TMDs two-dimensional monolayer film 201.

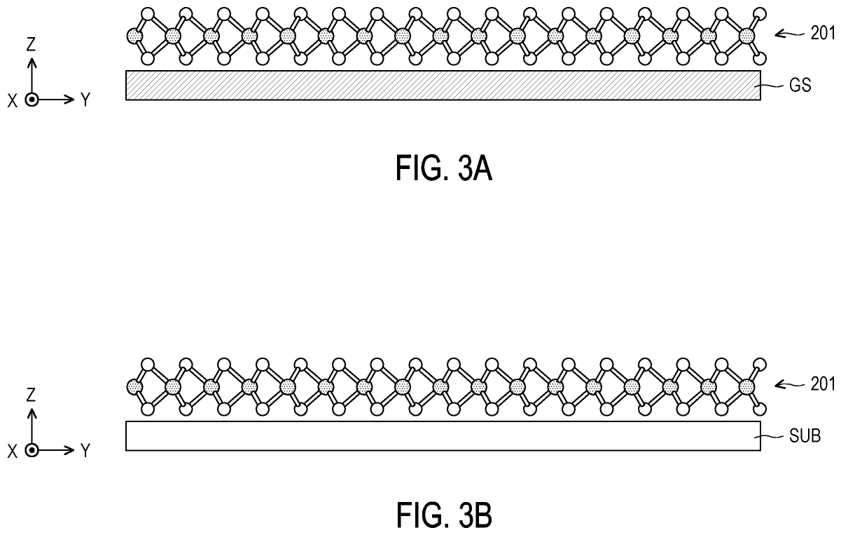

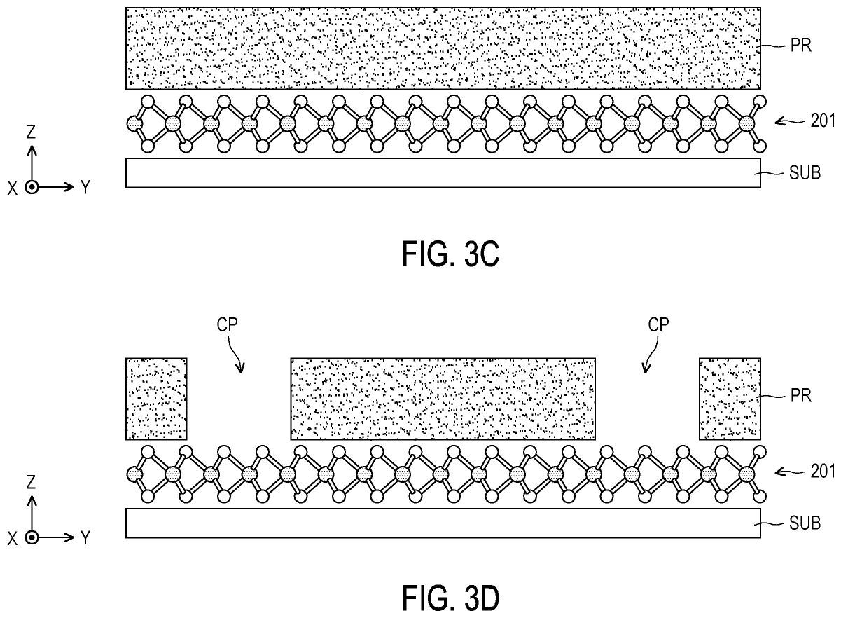

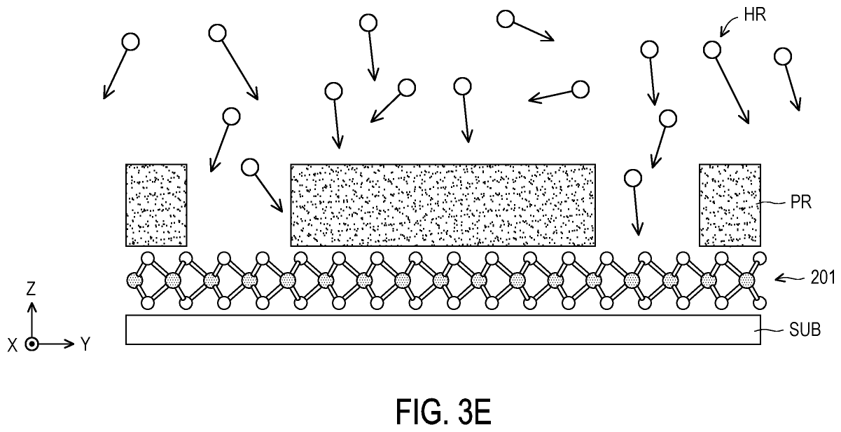

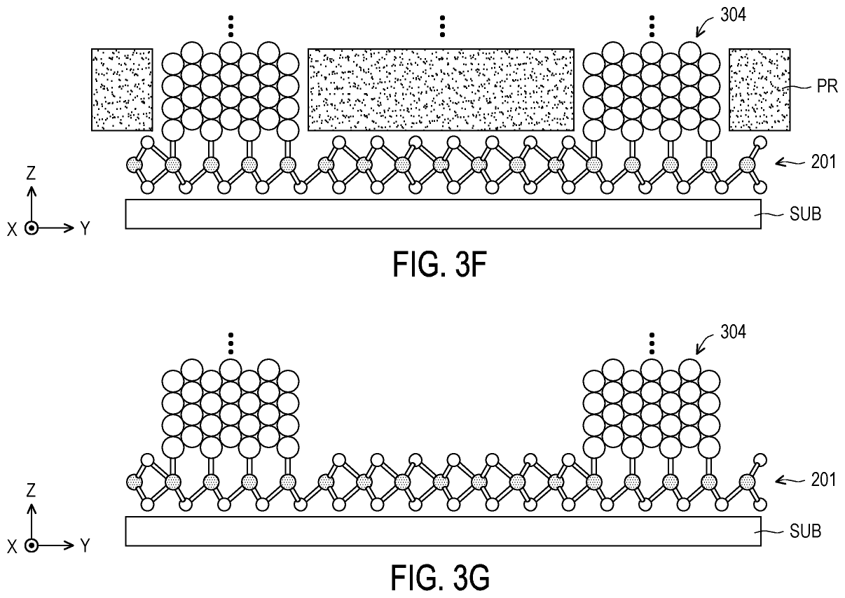

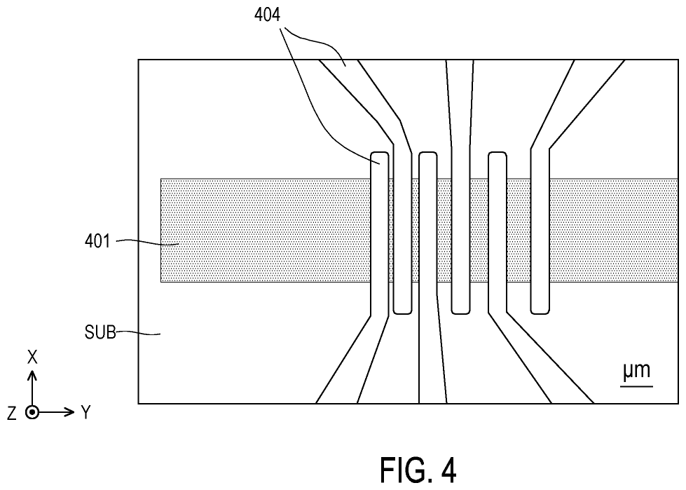

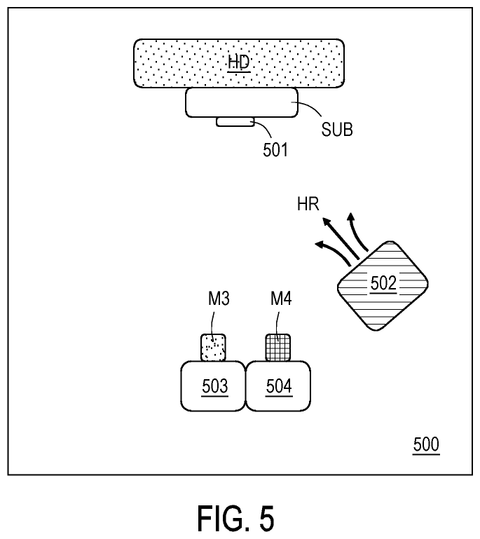

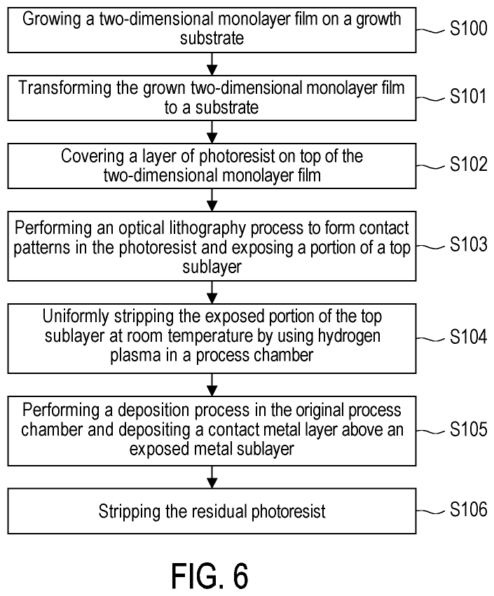

FIG. 3A to FIG. 3G are schematic diagrams illustrating structures of various stages in a manufacturing process of a layered semiconductor device according to some embodiments. FIG. 4 is a schematic top view illustrating a layered semiconductor device under an electron microscope according to some embodiments. FIG. 5 is a schematic diagram illustrating process equipment of a layered semiconductor device according to some embodiments. FIG. 6 is a flow chart illustrating an exemplary manufacturing method of a layered semiconductor device according to some embodiments.

Referring to FIG. 3A and FIG. 6, in step 100, the TMDs two-dimensional monolayer film 201 is grown on a growth substrate GS by, for example, metal oxide chemical vapor deposition (MOCVD) or PECVD. For example, the growth substrate GS may be a sapphire substrate, a liquid metal eutectic alloy of gallium indium (EGaIn) or an elastic substrate, which is not limited by the disclosure. In some typical embodiments, to use MOCVD to grow the TMDs two-dimensional monolayer film 201 is typically used in the front-end process.

Referring to FIG. 3B and FIG. 6, step 101 is performed. Then, the grown TMDs two-dimensional monolayer film 201 is transferred to, for example, a silicon crystal or silicon oxide substrate SUB. In some alternative embodiments, for example, a layer of polystyrene may be grown on the growth substrate GS, and then based on the hydrophobicity of the TMDs two-dimensional monolayer film 201 and the hydrophilicity of the polystyrene, the TMDs two-dimensional monolayer film 201 and the polystyrene are lifted-off from the growth substrate GS by using aqueous solution, and transferred to the silicon crystal or silicon oxide substrate SUB, and then the polystyrene is stripped.

Following FIG. 3B and referring to FIG. 3C, FIG. 3D, and FIG. 6, step 102 is performed. A layer of photoresist PR is covered on top of the TMDs two-dimensional monolayer film 201, and a digital light processing (DLP) technique is used to perform an optical lithography process to form contact patterns CP in the photoresist PR, and expose a portion of the top sublayer 101 not covered by the photoresist PR. In some embodiments, a thickness of the contact metal layer 104 may be adjusted by using a thickness of the photoresist PR. In some embodiments, various contact patterns CP are formed through a series of deposition, exposure and development steps. In some embodiments, a temporary protective mask (not shown) may be used to protect a portion of the top sublayer 101.

Following FIG. 3C and FIG. 3D and referring to FIG. 3E and FIG. 6, step 103 is performed. Hydrogen radicals HR generated by hydrogen plasma coming from a hydrogen ion source are used to perform a stripping process to uniformly strip the chalcogenide non-metal elements X in a portion of the top sublayer 101 not covered by the photoresist PR under a process temperature of room temperature (approximately 25° C. to 27° C.) and a vacuum environment with a process pressure of 10⁻³ to 100 Torr. The stripping process is chemical reactive etching, so that only specific reactive target elements are stripped without breaking the bonds between the bottom sublayer 103 and the metal sublayer 102, and the original corresponding bonds are still maintained between the metal sublayer 102 and the portion of the top sublayer 101 that is not stripped. Particularly, the disclosure may use, for example, Raman detection to confirm whether the chalcogenide non-metal elements X in the top sublayer 101 is completely stripped. Namely, by means of hydrogen radicals, after a period of treatment, it may be clearly learned that a characteristic peak of transition metal bis-sulfides (MX₂) has completely disappeared.

Following FIG. 3E and referring to FIG. 1, FIG. 3F, and FIG. 6, step 104 and step 105 are performed. Under the process temperature of room temperature and the high vacuum environment where the process pressure is maintained between 10⁻⁴ to 10⁻⁹ Torr, deposition equipment such as electron beam evaporation deposition (E-gun) is used in the original process chamber to perform deposition on the top surface TS3 of the metal sublayer 102 exposed by hydrogen radicals HR etching. For example, the contact metal layer 104 is deposited on the top of the exposed metal sublayer 102, so that the transition metal atoms of the metal sublayer 102 use dangling bonds to form metal bonds MB with the bottom contact metal atoms in the contact metal layer 104. The type of the contact metal atoms is the same as or similar to those in the aforementioned embodiments, and detail thereof is not repeated.

Following FIG. 3E and referring to FIG. 1, FIG. 3G, and FIG. 6, step 106 is performed. The residual photoresist PR on the sample after deposition of the contact metal layer 104 is stripped. For example, the sample after deposition of the contact metal layer 104 may be dipped in an acetone solution for photoresist lift-off. Finally, the two-dimensional layered semiconductor 100 with large-area metal bond electrodes is completed.

In some embodiments, the process conditions of the layered semiconductor 100 are compatible with the front-end-of-line, middle-end-of-line or back-end-of-line silicon process conditions.

Referring to FIG. 4, by viewing the layered semiconductor device from a top view in a Z direction, a device structure having a substrate SUB, a top sublayer 401, and a contact metal layer 404 may be observed.

Referring to FIG. 5, the process equipment for the layered semiconductor device includes: a process chamber 500, a substrate carrier HD, a substrate SUB, a layered semiconductor device sample 501, at least one hydrogen ion source 502, a plurality of crucibles 503, 504, and a variety of deposition metals M3, M4 targets.

Referring to FIG. 5, in some embodiments, the process chamber 500 is a relatively high vacuum chamber to provide stable temperature, pressure, and flow of reactive gases. In some embodiments, the process chamber 500 may provide the hydrogen ion source 502 and a vacuum environment for annealing, which helps to stabilize the thin film structure of the semiconductor device sample 501 to further reduce resistivity of semiconductor interconnect structures. In some embodiments, the substrate carrier HD provides sufficient stress support for the substrate SUB, and has certain stress buffering capability. The function and type of the substrate SUB are the same as or similar to those in the aforementioned embodiment, and details thereof are not repeated.

Referring to FIG. 1 and FIG. 5, in some embodiments, the hydrogen ion source 502 may provide hydrogen (gas) plasma to form hydrogen radicals to perform hydrogen (H₂) plasma pretreatment on the layered semiconductor device sample 501 to strip oxides from its surface. In some exemplary embodiments, a hydrogen source gas used in the hydrogen plasma treatment process may include NH₃, H₂, H₂O, etc. In the plasma hydrogenation process, at least one of various methods such as radio frequency (RF) plasma, microwave plasma, inductively coupled plasma (ICP) and remote plasma source (RPS) may be used to generate the hydrogen plasma.

Referring to FIG. 5, the crucibles 503 and 504 may be used to carry the deposition metals M3 and M4 targets. The deposition metals M3 and M4 targets may be replaced according to actual needs. In some embodiments, the deposition method of the disclosure includes the following steps. The substrate SUB is placed in the process chamber 500. At least one deposition cycle is performed to deposit the required deposition metals M3, M4 on the substrate SUB, where the at least one deposition cycle includes the following steps. In the crucibles 503 and 504, the required deposition metals M3 and M4 targets are selected. The hydrogen plasma is introduced from the hydrogen ion source 502 to chemically react with the semiconductor device sample 501 on the substrate, so as to strip a portion of a surface monoatomic layer of the semiconductor device sample 501. After i a portion of the surface monoatomic layer of the semiconductor device sample 501 is stripped, an in-situ metal deposition process is subsequently performed. In some embodiments, the at least one deposition cycle is performed under UV light irradiation and a hydrogen atmosphere.

In some embodiments, metals M3 and M4 are deposited on the top of the semiconductor device sample 501 in the process chamber 500 to serve as a contact metal layer, and after the contact metal layer is deposited, an insulating film is formed on the contact metal layer and a portion of a top layer of the semiconductor device sample 501. Then, other semiconductor devices may be formed on the insulating film. In some embodiments, the semiconductor device includes at least one of an electronic device, an optoelectronic device, or a combination thereof.

In some embodiments, the process conditions of the semiconductor device sample 501 are compatible with the front-end-of-line, middle-end-of-line or back-end-of-line silicon process conditions.

In some embodiments, compared with other back-end-of-line manufacturing methods, an advantage of the semiconductor device manufacturing method of the disclosure that adopts the two-dimensional semiconductor materials is that n-type and p-type devices may be constructed to form CMOS logic devices. In some embodiments, the two-dimensional semiconductor materials may also be continuously stacked in the back-end-of-line process to improve integration of the CMOS logic devices and various electrical application circuits, so as to develop compact CMOS logic circuits, which may be used for, for example, power gating or used as a repeater, etc.

Transistors formed from the two-dimensional layered semiconductor devices according to some exemplary embodiments may be used as switch elements included in at least one of logic devices, flash memory devices, resistive memories, magnetoresistive memory devices, and phase change memory devices.

Although some embodiments have been described above for illustrative purposes, the disclosure is not limited thereto and features of different embodiments may be combined as desired. For example, in some embodiments, the TMDs two-dimensional monolayer film 201 may include a thickness-modulated switchable material, i.e., a material adapted to switch an electronic character according to the number of stacked monolayers, such as PtSe₂, PdSe₂, or PtTe₂, etc. For example, in the case of PtSe₂, when one or several monolayers (in some embodiments, about five layers) are stacked on top of each other, the layer stack has semiconductor properties, and when a higher number of monolayers are stacked (in some embodiments, about six or more layers), then the layer stack has metallic properties. In some embodiments, one of such thickness-modulated switchable materials may serve as a two-dimensional semiconductor material of a channel region and may serve as a two-dimensional contact metal material, thereby adjusting a thickness (for example, the number of monolayers in the TMDs two-dimensional monolayer film 201) according to the desired electrical properties.

In some embodiments, the thickness-modulated switchable materials described above may be conveniently prepared through reaction of a precursor of transition metal atoms with another precursor of chalcogen atoms by CVP, PVD, ALD, or MBE. Regarding the precursor of the transition metal atoms, pure metals (for example, Pt or Pd), chlorides (for example, PtCl₂, PtCl₄, and PdCl₂) thereof or oxides (for example, PtO₂ and PdO) thereof may be used. Regarding the precursor of the chalcogen atoms, a chalcogen (for example, Se or Te) or a hydrogen chalcogenide (for example, H₂Se and H₂Te) may be used. In some embodiments, when chlorides and chalcogens are used as precursors, deposition of the thickness-modulated switchable material may be achieved through PVD at a temperature below 500° C. (for example, in a range of 300° C. to 400° C.). In some alternative embodiments, the thickness-modulated switchable material in a bulk form may be used as a material source to deposit the thickness-modulated switchable material.

Based on the above descriptions, by selectively stripping atoms from the first layer of the two-dimensional semiconductor surface and directly plating contact electrodes without changing the process environment and location, excellent metal-semiconductor junctions may be produced to greatly reduce contact resistance. By enhancing electron orbital coupling between the contact metal and the semiconductor, the density of states near a transmission band may also be increased, which greatly increases the efficiency of electron injection. In addition, the semiconductor device manufacturing method of the disclosure may implement reaction at room temperature, and use hydrogen atom radicals to strip atoms in the first layer of the surface without damaging a crystal structure of an underlying layer. On the other hand, the process conditions are simple, the reaction is easy to control, and it is completely compatible with the current silicon process, and may achieve a remarkable effect of reducing the contact resistance by more than two orders of magnitude.

The above are illustrations of some exemplary embodiments and should not be construed as limiting of the disclosure. Although several exemplary embodiments have been described, it will be easy for those skilled in the art to understand that many modifications may be made in the exemplary embodiments without departing from the novel teachings and advantages of the concept of the disclosure in essence. Therefore, all such exemplary modifications are intended to be included within the scope of the inventive concept as defined in the scope of the claims. In the scope of the claims, a means-plus-function clause is intended to cover the structures set forth herein as performing the functions, and is not only a structural equivalent but also an equivalent structure. Therefore, it is to be understood that the foregoing is an illustration of some various exemplary embodiments and should not be construed as being limited to the disclosed particular exemplary embodiments, and modifications to the disclosed exemplary embodiments and other exemplary embodiments are intended to be included within the scope of the attached claims. In addition, none of the disclosed exemplary embodiments is necessarily mutually exclusive. For example, some exemplary embodiments may include features described with reference to one figure, and may also include features described with reference to another figure.

The foregoing summarizes the features of several embodiments, so that a person having ordinary skill in the art may better understand the various aspects of the disclosure. A person having ordinary skill in the art should understand that the disclosure may readily be used as a basis for designing or modifying other processes and structures for carrying out the same purposes and/or achieving the same advantages of the embodiments described herein. A person having ordinary skill in the art should also realize that these equivalent constructions do not depart from the spirit and scope of the disclosure, and various changes, substitutions, and alterations thereto may be made without departing from the spirit and scope of the disclosure.

What is claimed is:

1. A semiconductor device, comprising:
a substrate;
a bottom sublayer, having a monoatomic layer thickness, disposed on the substrate and located at a bottom of the semiconductor device, and extending in a horizontal direction;
a metal sublayer, having a monoatomic layer thickness, and overlaying the bottom sublayer and electrically connected to the bottom sublayer in a manner of extending in the horizontal direction;
a top sublayer, having a monoatomic layer thickness, and disposed above a portion of the metal sublayer and electrically connected to the metal sublayer in the manner of extending in the horizontal direction; and
a contact metal layer, disposed above another portion of the metal sublayer, wherein a top surface of the contact metal layer is higher than a top surface of the top sublayer, a plurality of bottom layer contact metal atoms of the contact metal layer directly form corresponding bonds with a metal atom surface of the metal sublayer exposed after a portion of the top sublayer is stripped, and original corresponding bonds are maintained between the metal sublayer and the bottom sublayer.

2. The semiconductor device according to claim 1, wherein the original corresponding bonds are maintained between the metal sublayer and a portion of the top sublayer that is not stripped.

3. The semiconductor device according to claim 1, wherein the bottom sublayer, the metal sublayer, and the top sublayer form a monolayer film consisting of three monoatomic sublayers.

4. The semiconductor device according to claim 3, wherein the monolayer film semiconductor has at least one of flexibility and transparency.

5. The semiconductor device according to claim 3, wherein the metal sublayer comprises at least one or a combination of a transition metal element, a semi-metal element, and a noble metal element.

6. The semiconductor device according to claim 5, wherein the bottom sublayer and the top sublayer are composed of a plurality of elements of a same family in the periodic table.

7. The semiconductor device according to claim 6, wherein the elements of the same family are chalcogen elements.

8. The semiconductor device according to claim 1, wherein the plurality of bottom layer contact metal atoms of the contact metal layer and the metal atoms of the metal sublayer directly form the corresponding bonds in a process chamber at room temperature.

9. The semiconductor device according to claim 8, wherein a portion of the top sublayer is uniformly stripped by chemical reactive etching through hydrogen plasma in the process chamber.

10. The semiconductor device according to claim 9, wherein the hydrogen plasma in the process chamber etches a portion of the top sublayer without breaking bonds between the bottom sublayer and the metal sublayer.

11. The semiconductor device according to claim 10, wherein after the hydrogen plasma in the process chamber strips a portion of the top sublayer, the bottom sublayer and the exposed metal sublayer form a monolayer film consisting of two layers of atoms, and a top surface of the exposed metal sublayer has dangling bonds and directly forms a surface edge bond with the exposed metal sublayer during a deposition process of the contact metal layer in the process chamber.

12. The semiconductor device according to claim 9, wherein a following deposition process is performed on the metal sublayer etched by the hydrogen plasma in the process chamber while the process chamber maintains an original vacuum environment.

13. The semiconductor device according to claim 9, wherein the uniform stripping means that the hydrogen plasma in the process chamber strips the top sublayer having the monoatomic layer within a specific range under conditions of precisely controlling a predetermined hydrogen concentration and a predetermined reaction time.

14. The semiconductor device according to claim 1, wherein the contact metal layer is a polyatomic layer structure, and the contact metal layer is separated by the top sublayer and is laterally separated from each other in the horizontal direction.

15. The semiconductor device according to claim 1, wherein the bottom sublayer and the top sublayer are composed of a plurality of same elements.

16. The semiconductor device according to claim 1, wherein a contact resistance value between the contact metal layer and the metal sublayer is less than 1 kΩ·μm.

17. A manufacturing method of a semiconductor device, comprising:
forming a monolayer film composed of three monoatomic sublayers in a substrate, wherein the three monoatomic sublayers comprise:
a bottom sublayer, arranged on the substrate and located at a bottom of the semiconductor device, and forming a monoatomic layer extending in a horizontal direction;
a metal sublayer, overlaying the bottom sublayer and electrically connected to the bottom sublayer in the form of a monoatomic layer extending in the horizontal direction;
a top sublayer, arranged above a portion of the metal sublayer and electrically connected to the metal sublayer in the form of a monoatomic layer extending in the horizontal direction; and
a contact metal layer, disposed above another portion of the metal sublayer, wherein a top surface of the contact metal layer is higher than a top surface of the top sublayer;
uniformly stripping a portion of the top sublayer in a process chamber and maintaining original corresponding bonds between the metal sublayer and the bottom sublayer; and
performing a following deposition process in the process chamber, so that a plurality of bottom layer contact metal atoms of the contact metal layer directly form corresponding bonds with metal atoms of the exposed metal sublayer at a position where the top sublayer is uniformly stripped.

18. The manufacturing method of the semiconductor device according to claim 17, wherein the top sublayer is uniformly stripped through chemical reactive etching by hydrogen plasma in the process chamber at room temperature.

19. The manufacturing method of the semiconductor device according to claim 18, wherein the hydrogen plasma in the process chamber does not break the bonds between the bottom sublayer and the metal sublayer when etching a portion of the top sublayer, and original corresponding bonds are maintained between the metal sublayer and a portion of the top sublayer that is not stripped.

20. The manufacturing method of the semiconductor device according to claim 19, wherein the contact metal layer and metal atoms on a surface of the metal sublayer form metal bonds with respective d orbital domains.

21. The manufacturing method of the semiconductor device according to claim 18, wherein the hydrogen plasma generates hydrogen radicals to perform the chemical reactive etching when a process pressure is between 10⁻³ and 100 Torr.

22. The manufacturing method of the semiconductor device according to claim 17, wherein a process pressure of the deposition process is between 10⁻⁴ and 10⁻⁹ Torr.

23. The manufacturing method of the semiconductor device according to claim 17, further comprising:
after depositing the contact metal layer in the process chamber, subsequently forming an insulating film on the contact metal layer and the top sublayer; and
forming other semiconductor devices on the insulating film, wherein the semiconductor devices comprise at least one of electronic elements, optoelectronic elements, or a combination thereof.

24. The manufacturing method of the semiconductor device according to claim 23, wherein process conditions of the semiconductor device are compatible with front-end-of-line, middle-end-of-line, or back-end-of-line silicon process conditions.
